(19) United States
(12) Patent Application Publication
(10) Pub. No.: US 2015/0372096 A1
(43) Pub. Date: Dec. 24, 2015

(54) High Electron Mobility Transistors and Integrated Circuits with Improved Feature Uniformity and Reduced defects for Microwave and Millimetre Wave Applications

(71) Applicants: Ishiang Shih, Brossard (CA); Chunong Qiu, Brossard (CA); Cindy X. Qiu, Brossard (CA); Yi-Chi Shih, Los Angeles, CA (US)

(72) Inventors: Ishiang Shih, Brossard (CA); Chunong Qiu, Brossard (CA); Cindy X. Qiu, Brossard (CA); Yi-Chi Shih, Los Angeles, CA (US)

(21) Appl. No.: 14/120,716

(22) Filed: Jun. 20, 2014

(51) Int. Cl. H01L 29/20; H01L 29/778; H01L 29/205; H01L 27/06

(52) U.S. Cl. CPC H01L 29/2003; H01L 27/0629; H01L 29/7786; H01L 29/205

(57) ABSTRACT

High mobility transistors and microwave integrated circuits with an improved uniformity of the width of the smallest of features, an increased lithographic yield and reduced defects in the active components are provided. Before and during fabrication, a first grooving process is performed to partially or completely remove composite epitaxial layers in the field lanes to reduce the initial bow to be smaller than DOF range and to improve the uniformity of the critical dimension. A second grooving process may also be performed to remove composite epitaxial layers in the dicing lanes to further improve the uniformity of the width of the smallest features for the devices and circuits to be made.

### FIELD OF INVENTION

The present invention is related to transistor devices and circuits for power switching and microwave amplification. More specifically, it is related to high mobility transistors and microwave integrated circuits with improved critical dimension uniformity, increased lithographic yield and reduced defects in the active components.

### BACKGROUND OF THE INVENTION

In addition to devices based on a metal-oxide-semiconductor (MOS) structure, an insulated gate bipolar transistor (IGBT) structure and a lightly doped drain metal-oxide-semiconductor (LDMOS) structure which are commonly used for power switching and signal amplification, a new class of semiconductors based on III-nitrides are being developed. This is due to the needs to enhance the circuit performance by having higher power handling capability and to reduce the unwanted power loss, beyond what the present silicon-based devices can provide. There is also a need to provide devices which can perform at high frequencies, preferably in the millimetre wave regions, higher than 10 GHz or even higher than 100 GHz.

The new class of III-nitride semiconductors include the ones where III represents Al, Ga and In. Examples of the new class of semiconductors include AlN, GaN, InN, AlGaN, InGaN and their alloys. Some of these new III-nitrides have exceptional electronic properties suitable for devices having reduced unwanted power losses and increased power handling capability over a wide range of frequencies up to millimetre waves. Such performance characteristics are made possible due to the inherent properties including short energy relaxation time, τ, large energy bandgaps and high electron mobility as compared to silicon and gallium arsenide. Due to the short relaxation time and large energy bandgaps, devices fabricated using these III-nitride semiconductors and their alloys have breakdown electric fields substantially greater than the silicon or gallium arsenide counter parts. For example, the breakdown electric field for AlGaN is 3.0×10⁶ V/cm which is about 10 times of that for Si and GaAs and devices made of AlGaN can sustain larger voltages with the same device dimensions or thicknesses during the operation. As a result, the critical temperatures of some of the III-nitrides for stable operation are substantially higher than GaAs and Si. For example, the critical junction temperature for stable operation is 250° C. for silicon devices, 400° C. for GaAs devices and 600° C. for devices based on III-nitrides. Combining the high critical breakdown electric field, high mobility and high critical operation temperature, it is evident that III-nitrides devices and circuits are idea for high power switching and high frequency millimetre wave circuit applications and it is possible for the III-nitrides to replace some of the high frequency applications currently provided by GaAs technology.

Currently, the III-nitride layers are often deposited on sapphire (Al₂O₃), silicon carbide (SiC) and silicon (Si) substrates. Due to the difference between the III-nitrides materials and the substrates (sapphire, SiC or Si) used, there is often a mismatch in lattice constants and a difference in thermal expansion coefficients between the substrates and the III-nitride layers. These thermal expansion coefficient difference and lattice mismatch will induce strain or stresses in the epitaxial III-nitride thin films during cooling or heating period. They also lead to strain and stresses in the sapphire, SiC and Si substrates and create a deformation of the substrates, which might cause critical dimension uniformity to deteriorate and induce defects such as microcracks in the III-nitride epitaxial layers.

In FIG. 1a, the cross-section of a wafer or a substrate (100) for III-nitride deposition is shown. The substrate can be sapphire, SiC or Si and has a diameter (100D) and a thickness (100T). The thickness uniformity of the wafer is given by total thickness variation (TTV) which can be controlled to better than 1% for a 6 inch diameter wafer with a thickness of about 1 mm. Flatness of the wafer (100) is given by bow which is as small as 3 μm. Without any lattice mismatch and thermal expansion coefficient difference, when thin layers (110, FIG. 1b) of a thickness (110T) are deposited on the substrate (100), there will be no strain or stress between the two. The lack of strain or stresses will not lead to deformation of the substrate so the substrate remains flat. However, with lattice mismatch and thermal expansion coefficient difference between the substrate (100) and the thin layers (110), concave or convex deformation of the substrate might occur. As depicted in FIG. 1c, a concave deformation of the substrate (100) is shown and the thin film layers (110) deposited on the substrate will have tensile or compressive stresses in them. The surface of the thin layers (110) with the concave deformation defines a first sphere with a first sphere center (120) and a first sphere radius (130). The distance between a first reference plane (140) and the lowest point of the thin layer's surface defines a first bow (160). Alternately as shown in FIG. 1d when the lattice mismatch and thermal expansion coefficient difference create a convex deformation in the substrate (110), the bottom surface of the substrate (100) defines a second sphere with a second sphere center (120′) and a second sphere radius (130′). The distance between a second reference plane (140′) and the highest point of the substrate bottom surface defines a second bow (160′).

Conventional manufacturing method for devices or circuits based on the III-nitride layers on a wafer involves several photolithography processes. Each requires one photomask. A typical photolithography process includes (1) applying photoresist and soft baking, (2) exposing to transfer the patterns on the photomask to a selected region or field in the photoresist on the wafer then step and repeat or step and scan over the entire wafer, (3) developing the transferred patterns in each field in a developer, (4) rinsing and drying and (5) examine patterns and determining critical dimensions of features in the patterns. After the photolithography process, either etching of epitaxial layers in the exposed regions not covered by the photoresist or deposition of metal layers in exposed regions will be performed. After the etching or deposition, the remaining photoresist will be removed and the wafer cleaned for subsequent photolithography process. One of the key steps in photolithography is (2) transferring of patterns on the photomask onto a field in the photoresist, which is made either using a stepper or a scanner. As seen in FIG. 2, a simplified schematic diagram for a stepper (200) is shown. It has a light source (210) and a lens (220) of a diameter (220D). Said light source illuminates a photomask (230) of a thickness (230T) and project an image (240) of the photomask pattern on the photoresist (250) coated wafer (260), forming a field of image (270) having a field image width (270W) and a field image length (270L). After exposing of a first field, the wafer is moved to a new position for exposing of a second field. The above process is repeated for the entire wafer surface.

In an imaging system, the minimum feature in a printed photoresist patterns is given by: FS=k₁ λ/NA, here k₁ is a constant of about 0.3-0.4, λ is the wavelength of the light source and NA is numerical aperture of the lens (220). As values of k₁ and NA are substantially constant for a given stepper or scanner, a light source with a short wavelength is used to achieve a small FS. A stepper using i-line of Hg lamp has a wavelength λ=365 nm whereas a scanner using an ArF laser has a wavelength λ=193 nm. Another important parameter in a stepper or a scanner is the depth of focus (DOF) (280) which is a parameter defining the imaging performance of the photoresist. It is the depth range of the wafer over which the feature sizes are within the specifications. Value of DOF is typically defined as the wafer plane height variation that leads to a ±10% variation of the critical dimension (CD) or width of the smallest features printable in the stepper or scanner.

TABLE 1
DOF for different generation of steppers and scanners

| Wavelength | NA | DOF (nm) | Source |
|---|---|---|---|
| 365 nm | 0.6 | 1,000 | Hg lamp |
| 248 nm | 0.7 | 700 | KrF laser |
| 193 nm | 0.75 | 500 | ArF laser |

In Table 1 the wavelength, NA and DOF are listed for steppers and scanners using different light sources. It is noted that the values of DOF are quite small and can pose difficulties when such systems are used to project images of patterns on a photomask onto photoresist applied on a wafer with a large bow or deformation, considering the need of uniform critical dimension (CD) over a single field. As the value of bow exceeds the DOF of the stepper or scanner, the critical dimension (CD) or the width of the smallest features in the projected and developed photoresist patterns will have width variation from one location to the others in the field. This variation in the smallest feature dimension will degrade the electronic performance of devices or circuits. In order to ensure the success in the photolithography imaging, a wafer with a bow is held in position against a wafer chuck by an attracting force. Such attracting force often induces additional strain or stresses superimposing on the original strain or stresses already induced during the deposition of composite epitaxial layers. The additional strain or stresses will have further effects on the performance of the devices or circuits fabricated.

### SUMMARY OF THE INVENTION

The present invention provides high mobility transistors and microwave integrated circuits based on III-nitride epitaxial layers or III-arsenide epitaxial layers with improved critical dimension uniformity and reduced defects in active components.

### BRIEF DESCRIPTION OF THE SEVERAL VIEWS OF THE DRAWINGS

FIG. 1a is a cross-section of a wafer or substrate for III-nitride layers deposition with a diameter (100D) and a thickness (100T). FIG. 1b shows the substrate after the deposition of III-nitride layers assuming zero lattice mismatch and thermal expansion coefficient difference. FIG. 1c shows the substrate with a concave deformation when there is lattice mismatch and thermal expansion coefficient difference causing tensile stresses. FIG. 1d shows the substrate with a convex deformation when the lattice mismatch and thermal expansion coefficient difference create compressive stresses in said film.

FIG. 2 shows a simplified schematic diagram of a stepper, with a light source (210), a lens (220), a photomask (230) and a substrate (260). The light source illuminates the photomask and project an image of the photomask pattern on the photoresist (250) applied on the substrate forming a field of image (270) having a field image width and a field image length.

FIG. 3a shows a portion of a concave substrate with a deformation bow (330) substantially smaller than the depth of focus (280) of the stepper or scanner. FIG. 3b shows a portion of concave substrate with more severe deformation so that DOF (280) of the imaging system is smaller than the deformation bow (330′). FIG. 3c is a substrate with severe convex deformation and the bow (330″) exceeds DOF (280) of the imaging system.

FIG. 4a shows microcracks (410, 420 and 430) induced in the composite epitaxial layers (402). FIG. 4b shows a top view of an ideal HEMT in the channel region epitaxial layers, FIG. 4c is a cross-sectional view of the HEMT along line A-A′.

FIG. 5a is a schematic cross-sectional view of a wafer (510) with composite epitaxial layers (520) and a first photoresist layer (540) on top, showing a concave deformation with a bow (530): FIG. 5b shows a top view of the wafer (510) with composite epitaxial layers completely or partially removed from the X-axis field lanes and the Y-axis field lanes to release a portion of strain or stresses and FIG. 5c is a cross sectional view of the wafer along line B-B′, showing a reduced bow (590) to a value smaller than the DOF (280) to facilitate the imaging. FIG. 5d is the same wafer shown in FIG. 5c after a photoresist layer (585) is applied on the wafer top surface, showing an even smaller bow (590′).

FIG. 6a is a schematic cross-sectional view of a field (600) having a substrate (610) with composite epitaxial layers (620) and a first photoresist layer (640), showing a concave deformation with a bow (630). FIG. 6b shows a top view of the field (600) with composite epitaxial layers completely or partially removed from the X-axis dicing lanes and the Y-axis dicing lanes to further release a portion of strain or stresses. FIG. 6c is a cross sectional view of the field (600) along line C-C′, showing a reduced bow (690). FIG. 6d shows the same field (600) after a photoresist layer (695) is applied on the top surface, showing an even smaller bow (690′).

FIG. 7a shows sample (700) having a substrate (710) with composite epitaxial layers (720). FIG. 7b shows a first photoresist layer applied and developed to create dicing lanes photoresist cavity (730C) to expose the composite epitaxial layers in the dicing lane. FIG. 7c shows (700) after a majority of the exposed composite epitaxial layers except the buffer layer (721) in said dicing lanes have been removed or etched forming a composite epitaxial layer cavity (720C). FIG. 7d shows (700) after a portion of said buffer layer (721) has been removed forming a buffer layer cavity (721C′). FIG. 7e is the situation when the etching is performed so that said exposed buffer layer (721) is completely removed to expose the substrate and forming buffer layer cavity (721C). FIG. 7f shows (700) after the exposed substrate (710) is over etched so that material from a top substrate region is removed to form a substrate top cavity (710C).

FIG. 8 is a simplified schematic top view of a typical low noise amplifier MMIC microchip with two stage HEMTs (840, 850) and passive components (861, . . . , 888) for biasing including resistors, capacitors and inductors, showing the relatively small areas taken by the HEMTs.

FIG. 9a is a schematic top view of a HEMT, showing four dicing lane edges (911, 912, 913, 914) and four composite epitaxial HEMT region edges (921, 922, 923, 924). The values of the four distances (921D, 922D, 923D, 924D) between adjacent dicing lane edges and composite epitaxial HEMT region edges are kept to be greater than 100 μm and more preferably more than 150 μm according to this invention in order to avoid the effects due to the presence of dicing lanes and the associated reduction in strain and stresses in said composite epitaxial layer region on said HEMT. FIG. 9b shows a cross-sectional view of the HEMT shown in FIG. 9a along the line A-A′.

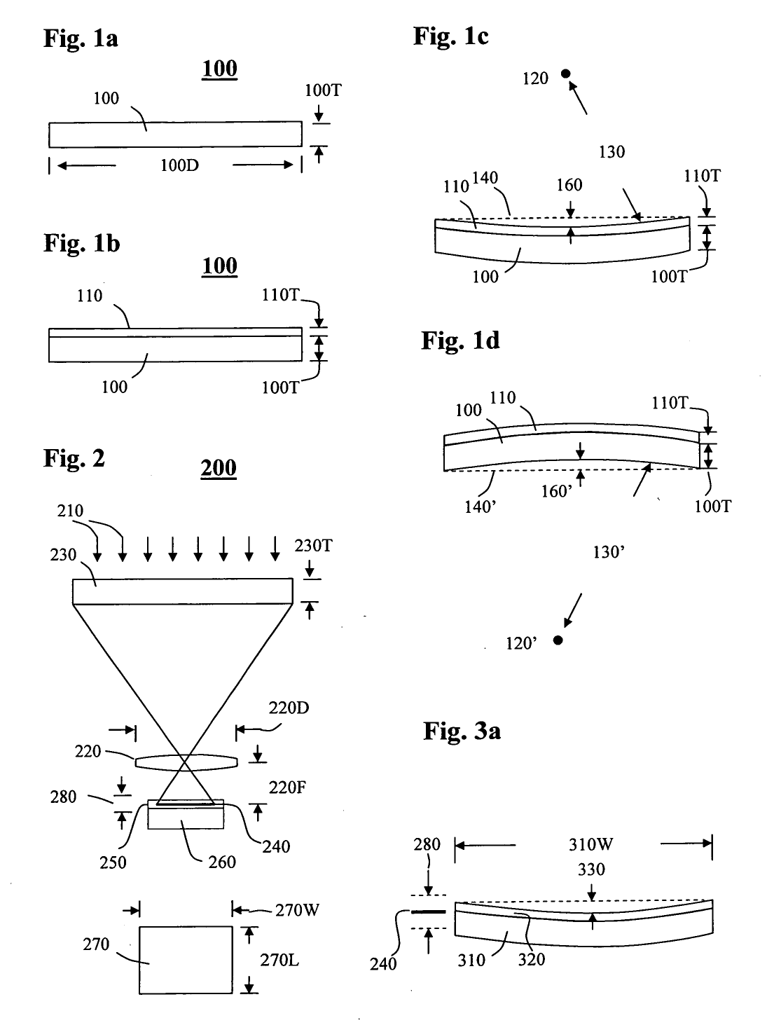

### DETAIL DESCRIPTION OF THE PREFERRED EMBODIMENTS

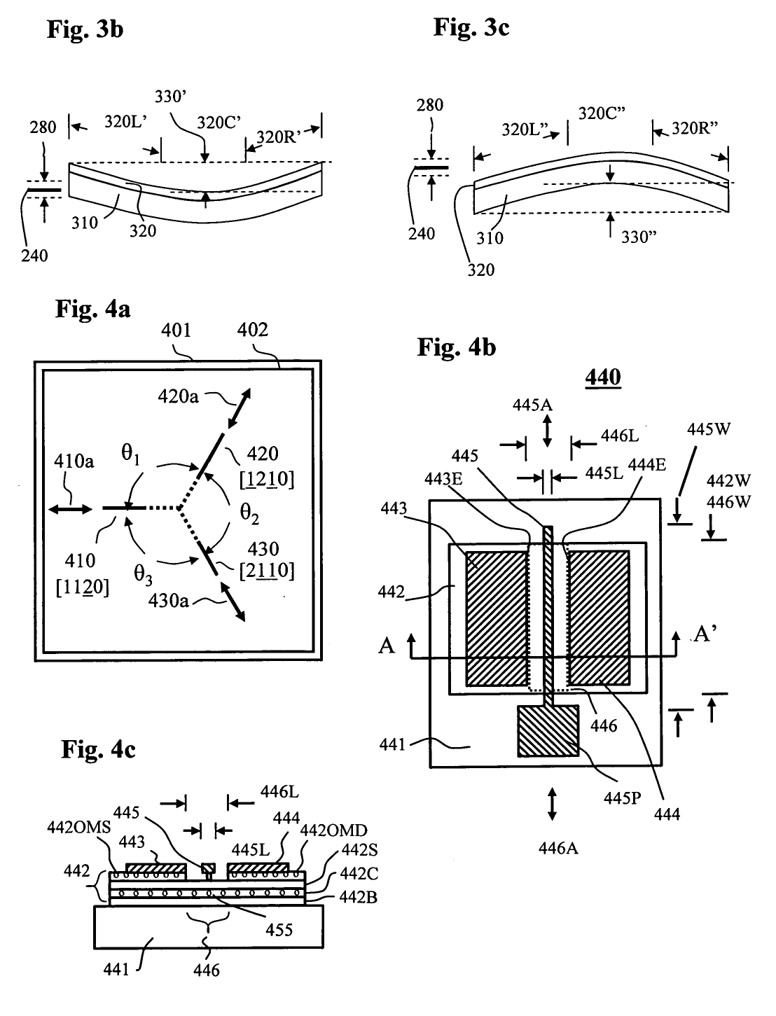

FIG. 3a shows a portion of a wafer or a substrate (310), with a photoresist layer (320) applied on it and the width of the substrate portion (310W) is substantially the same as the field image width (270W) shown in FIG. 2. The substrate portion (310) has a concave deformation and a bow (330) which is substantially smaller than the depth of focus (DOF, 280) of the stepper or scanner. Under these conditions, when an areal image is projected onto the photoresist layer in the central region, the photoresist layer in the entire field will be within the depth of focus so that uniform critical dimension (CD) (or uniform width of the smallest feature) can be obtained in the entire field.

When the deformation of a concave substrate portion (310) is severe, the bow (330′) is substantially greater than DOF (280) of the imaging system, as shown in FIG. 3b. Under these conditions, when an areal image is projected onto the photoresist surface, only the photoresist layer in the central region (320C′) will be within the depth of focus so that uniform critical dimension can be obtained. In the two outer regions (320L′, 320R′), photoresist layers are outside the DOF range and hence CD values or uniformity will degrade. In other words, uniform critical dimension cannot be obtained consistently across the entire field. The variation of width of the smallest features from the specifications will exceed ±10%, which is the deviation tolerance often used in defining DOF.

When the deformation of a convex substrate portion (310) is severe, the bow (330″) is substantially greater than DOF (280) of the imaging system, as shown in FIG. 3c. Under these conditions, when an areal image is projected onto the photoresist layer, only the photoresist layer in the central region (320C″) will be within the depth of focus so that uniform width of the smallest features CD can be obtained. In the outer regions (320L″, 320R″), photoresist layers are outside the DOF and hence CD values or uniformity will degrade. Therefore, uniform critical dimension cannot be obtained consistently in the entire field. The variation of width of the smallest features CDs from the specifications will exceed ±10%, which is the deviation tolerance often used in defining DOF.

During exposing, a substrate must be flat within the entire field width. This is often achieved by applying an attracting force to the wafer against a chuck either by an electrostatic force or by vacuum. Such a force deforms the wafer and the composite epitaxial layers on it and induces more strain or stresses on top of the existing strain or stresses induced in the composite epitaxial films during deposition, hence increases strain or stresses to an even more severe level. These strain or stresses lead to creation of unwanted microcracks (410, 420, 430, FIG. 4a) in composite epitaxial layers (402) of III-nitrides such as InGaN—AlGaN—GaN deposited on (111) oriented silicon substrate (401). It is noted that the occurrence of the above mentioned microcracks may be in random fashion in term of location in a composite epitaxial layer. The microcracks (410, 420, 430) each has a microcrack long axis (410a, 420a, 430a) and may appear at locations in a random fashion with angle (θ₁, θ₂, θ₃) between corresponding adjacent microcracks (410-420, 420-430, 430-410). This is the case when epitaxial films of GaN, AlN, InN and their alloys (0001) are deposited on Si (111) substrate, with three equivalent primary microcrack directions along [1120], [1210] and [2110].

These unwanted microcracks can have detrimental effects to active devices such as HEMTs in a switching circuit of MMIC when these microcracks are within or close to the active channel. In FIG. 4b, a top view of an HEMT (440) is given. It comprises a silicon substrate (441), a composite epitaxial layer region (442) which is InGaN—AlGaN—GaN in this example having an epitaxial layer region width (442W), a source (443), a drain (444) and a gate (445). Said gate has a gate length (445L), a gate width (445W). Said source (443) has a first source edge (443E) facing said gate and said drain (444) has a first drain edge (444E) facing said gate. Epitaxial layer region between said source and drain defines a channel region (446) having a channel region length (446L), a channel region width (446W) which is substantially the same as said epitaxial layer region width (442W). Said channel region (446) has a channel region long axis (446A) which is substantially parallel to said first source edge (443E) or said first drain edge (444E), whereas said gate has a gate long axis (445A) which is substantially parallel to said channel region long axis (446A).

Refer now to FIG. 4c where a cross-sectional view of HEMT (440) taken along the line A-A′ in FIG. 4a is shown. Here the composite epitaxial layer region (442) is formed by the epitaxial deposition and etching and consists of at least fours sub-layers: an epitaxial buffer layer (442B) to ensure adhesion and lattice relaxing, a conductive channel layer (442C), a Schottky barrier layer (442S), a source ohmic layer (4420MS) and a drain ohmic layer (4420MD). Materials for the buffer layer (442B) may be AlN—AlGaN multiple layers and that for the conductive channel layer (442C) may be GaN or InGaN. Materials for the Schottky barrier layer (442S) may be AlGaN whereas materials for said source ohmic layer (4420MS) and drain ohmic layer (4420MD) may be heavily doped GaN or InGaN. There is a high density of charge carriers of electrons (indicated by circles) in the source ohmic layer (4420MS) and the drain ohmic layer (4420MD) induced by impurity doping to facilitate ohmic contacts to source (443) and drain (444). The source (443) and drain (444) are metal layers deposited to make ohmic contact to the source ohmic layer and the drain ohmic layer.

In the conductive channel layer (442C), there are charge carriers or electrons (455) shown as circles with a density controlled during the epitaxial deposition of the composite (InGaN—AlGaN—GaN) epitaxial layer so that appropriate stresses will allow a sheet resistance of the conductive channel layer to be in the order of 100 to 200 ohm per square or less. In the ON state, for a HEMT with a ratio of channel width (446W) to channel length (446L) of 100, the resistance of the channel region between said source and drain is equal to 1 ohm or 2 ohm which can be neglected for certain switching applications. When a voltage is applied between said gate (445, 445P) and said source (443) so that majority of the charge carriers or electrons are expelled from the conductive channel layer (442C) immediately below the gate (445). The expelling of charge carriers or electrons is due to electric fields created in the Schottky barrier layer (442S) immediately below said gate, by the voltage applied between the gate and the source. The expelling lead to depletion of charge carriers or electrons in the conductive channel layer (442C) immediately below gate (445) and increases its resistivity by several orders of magnitude. The HEMT is now in an OFF state where resistance between the drain (444) and the source (443) increases by several orders of magnitude from the original ON resistance value of 1 ohm. The HEMT in the above description is an ideal device without been affected by the unwanted presence of microcracks and acts as an electronic switch.

When intermediate voltages are applied between said gate and source, intermediate amounts of charge carriers or electrons will remain so that the resistance between the drain and the source will have intermediate values. When a voltage is applied between the drain and the source, intermediate currents will be allowed to flow from drain to source. With the above behaviour, the HEMT acts as an electronic amplifier for alternating currents or signals, which may vary at microwave or millimetre wave frequencies. In order to obtain good device performance for both switching and signal amplification, the conductive channel in ON state must have continuous distribution of charge carriers or electrons.

As indicated before, the above description of operations of the HEMT (440) in FIG. 4b and FIG. 4c is made assuming no unwanted microcracks formed in or near the conductive channel layer. The microcracks can form throughout the epitaxial deposition and subsequent cooling, during the fabrication of devices or circuits and all through the operation.

### First Grooving Process to Partially or Completely Remove Composite Epitaxial Layers in the Field Lanes

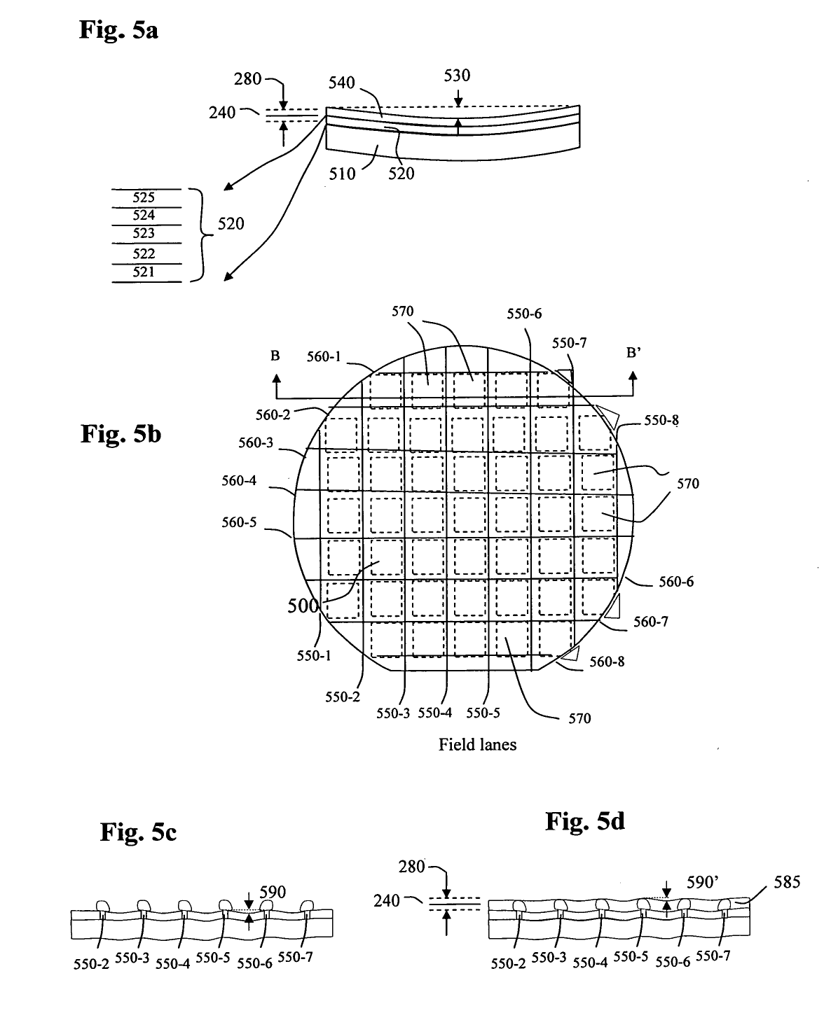

According to one embodiment of this invention, before fabricating devices and circuits on a wafer (510) with composite epitaxial layers (520) and having a substantial initial bow (530) as shown in FIG. 5a, an first grooving process involving partial or complete removal of the composite epitaxial layers (520) in all of the field lanes is carried out for facilitating subsequent photolithography processes during the fabrication of devices and circuits using a stepper or scanner. Such grooving process is done to reduce the initial bow (530) to be smaller than DOF range (280) and to improve the uniformity of the critical dimension or the smallest features for the devices and circuits to be made. The composite epitaxial layers (520) comprise a buffer layer (521), a conductive channel layer (522), a Schottky barrier layer (523), a ledge layer (524) and a doped ohmic contact layer (525). The wafer (510) is selected from a material group of silicon, SiC, sapphire and GaAs. The composite epitaxial layers (520) can be AlN, GaN, InN, GaAlN, GaInN, InAlN and their alloys and mixtures. Materials of the composite epitaxial layers (520) can also be selected from a group including: AlAs, GaAs, InAs, GaAlAs, GaInAs, InAlAs and their alloys and mixtures.

In order to carry out this grooving process, a first photoresist layer (540) is applied on the surface of the composite epitaxial layers (520) coated wafer (510) for a first photolithography process and a first etching process. Exposing and developing said first photoresist layer using a first photomask to remove photoresist and to expose the composite epitaxial layers (520) in the X-axis field lanes (550-1, 550-2, 550-3, 550-4, 550-5, 550-6, 550-7, 550-8, see FIG. 5b) and the Y-axis field lanes (560-1, 560-2, 560-3, 560-4, 560-5, 560-6, 560-7, 560-8). Each of the X-axis and Y-axis filed lanes is located between two adjacent fields (570). The X-axis and Y-axis filed lanes divide the wafer (510) into plurality of fields (570). Etching said exposed composite epitaxial layers (520) in said X-axis field lanes and Y-axis field lanes to release a portion of strain or stresses caused in said wafer (510). Said etching of the composite epitaxial layers is performed preferably by dry etching such as reactive ion etching or plasma etching. Said etching can be made completely through said composite epitaxial layers or partly through the top conductive channel layer including a portion of said buffer layer. After the above etching of the composite epitaxial channel layers, the first photoresist is removed and the strain and stresses in the wafer has been substantially released so that the final bow (590, FIG. 5c) is smaller than initial bow (530, FIG. 5a). The wafer (510) is now ready for subsequent photolithography processes for the device and circuit fabrication with better uniformity for the width of the smallest features CD.

The first photolithography process for the first grooving may be implemented using a first mask with 1 to 1 projection or proximity printing. This is because the resolution of field lanes is often large in the order of 50 μm or 100 μm. Alternately, the first photolithography may well be achieved using a stepper due to the large field lanes dimensions and due to the fact that the field lanes are located in four periphery regions. With the complete removal or partial removal of the composite epitaxial channel layers in the field lanes, the strain or stresses in the substrate wafer is partially removed so that the final bow (590) will have a value substantially less than the initial bow (530) before the etching of the materials in the field lanes. After applying a second photoresist (585) on the released wafer, the localized region bow (590′, FIG. 5d) will have a value smaller than the DOF (280) to facilitate the imaging.

To improve the thermal stability of the present HEMT, there is a need to deposit a layer of passivation material such silicon nitride and silicon oxide nitride, silicon oxide nitride, magnesium oxide, hafnium oxide, aluminum oxide and the mixtures. As the technology of passivation for transistor devices is not the scope of this invention, more description will not be given.

The substrate may be silicon, silicon carbide, sapphire and GaAs as long as their crystalline quality is suitable for epitaxial growth of the III-nitride layers. Materials for the III-nitride layers may include AlN, GaN, InN, AlGaN, InGaN, AlInN and their alloys. Materials for drain contact and source contact can be selected from a combination of metals such as Ti, W, Pt, Al, Au, Cu as long as the first metal contacting the composite epitaxial layers can make a low contact resistance. Whereas materials for said gate can be selected from a material group of Ni, Ta, W, Pt, Al, Ti as long as the first metal contacting the channel gate region can make a rectifying Schottky contact.

### Second Grooving Process to Partially or Completely Remove Composite Epitaxial Layers in the Dicing Lanes

The most important photolithography process in device or circuit fabrication is for creation of the smallest features. For high electron mobility transistor (HEMT), this will be the one for the creation of gate and more specifically for the creation of the stem portion of said gate. For a HEMT or circuit for microwave and millimetre wave applications, the length of said gate stem portion (or CD) will be as small as 100 nm or even less than 50 nm. To achieve such a small length for said gate stem portion, a scanner with a light source of short wavelength must be used. The wavelength for the scanners for this purpose is 193 nm and the associated DOF is small: 500 nm. Therefore, the complete removal or partial removal of materials from the field lanes alone may not be sufficient to achieve the required wafer surface flatness to obtain the required CD uniformity over the entire fields.

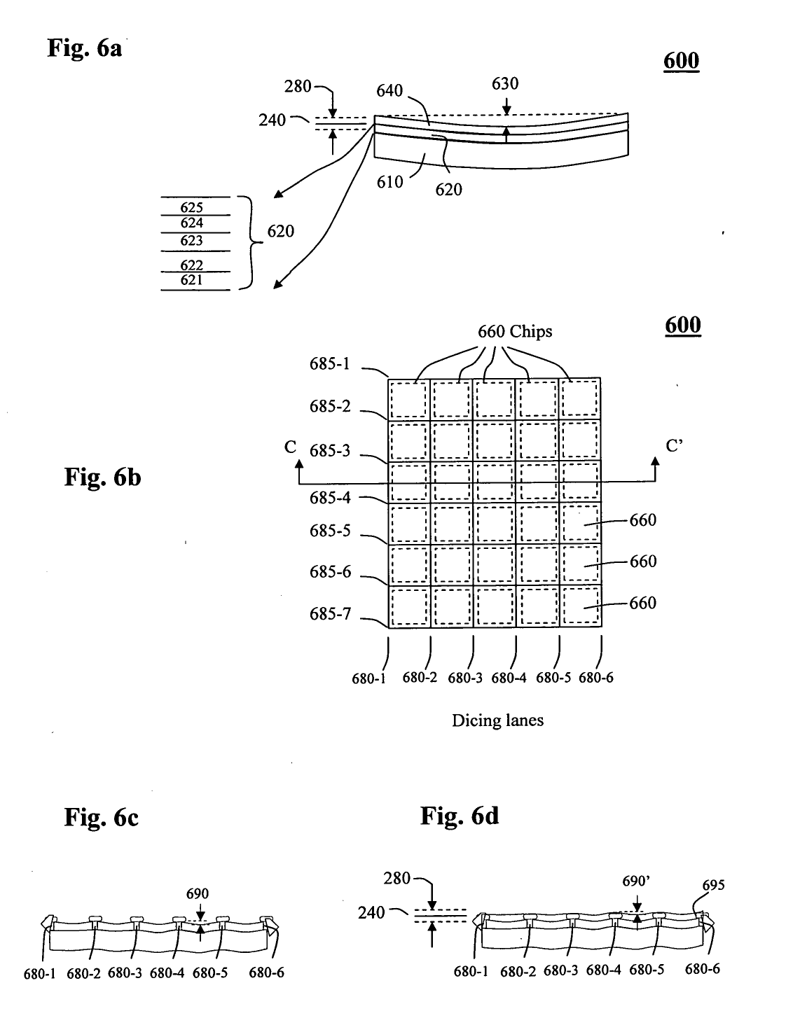

According to another embodiment of this invention, before the fabrication of devices and circuits, a second grooving process is carried out to remove composite epitaxial layers (620) in the dicing lanes as shown in FIGS. 6a-6d for facilitating subsequent photolithography processes during the fabrication of devices and circuits using a stepper or scanner. The second grooving process can further reduce the bow of the fields and to improve further the uniformity of the critical dimension or the smallest features for the devices and circuits to be made. FIG. 6a shows a field (600) having a substrate (610) and composite epitaxial layers (620) with a substantial initial bow (630). The composite epitaxial layers (620) include a buffer layer (621), a conductive channel layer (622), a Schottky barrier layer (623), a ledge layer (624) and a doped ohmic contact layer (625). The substrate (610) is selected from a material group of silicon, silicon carbide, sapphire and GaAs. The composite epitaxial layers (620) can be AlN, GaN, InN, GaAlN, GaInN, InAlN and their alloys and mixtures. Materials of the composite epitaxial layers (620) can also be selected from a group including: AlAs, GaAs, InAs, GaAlAs, GaInAs, InAlAs and their alloys and mixtures. The field (600) in FIGS. 6a and 6b could be viewed as the same as the field (570) illustrated in FIG. 5b.

In order to carry out second grooving process to further improve uniformity of the smallest features, a first photoresist layer (640, FIG. 6a) is applied on the surface of the composite epitaxial layers (620) on top of the substrate (610) for a first photolithography process and a first etching process. Exposing and developing the first photoresist layer (640) using a first photomask to remove photoresist and to expose the composite epitaxial layers (620) in the X-axis dicing lanes (680-1, 680-2, 680-3, 680-4, 680-5, 680-6) and the Y-axis dicing lanes (685-1, 685-2, 685-3, 685-4, 685-5, 685-6, 685-7) between adjacent chips (660). The X-axis dicing lanes and Y-axis dicing lanes divide the field (600, which is the same as 570 in FIG. 5b) into plurality of chips (660). Etching said composite epitaxial layers (620) in said exposed dicing lanes to release a portion of strain or stresses caused in said substrate (610). Said etching can be made completely through said composite epitaxial layers (620) or partly through the top conductive channel layer (622) and including a portion of said buffer layer (621). The etching of said composite epitaxial layers (620) is performed preferably by dry etching, such as reactive ion etching or plasma etching. After the above etching of the composite epitaxial channel layers, the first photoresist (640) is removed and the strain and stresses in the substrate (610) has been substantially released so that the final bow (690, FIG. 6c) is smaller than the initial bow (630, FIG. 6a). (600) is now ready for subsequent photolithography processes for the device and circuit fabrication with better uniformity of width of the smallest features CD.

The first photolithography process for the second grooving may be implemented using a first mask with 1 to 1 projection or proximity printing. This is because the resolution or width of dicing lanes is often large. Alternately, the first photolithography may well be achieved using a stepper due to the large chip dimensions. With the removal or partial removal of composite epitaxial channel layers in said dicing lanes, the strain or stresses in the substrate is partially removed so that the final bow (690) is reduced from the initial bow (630) before the etching of the materials in the scribing or dicing lanes. After applying a second photoresist (695) on the released substrate, the localized region bow (690′, FIG. 6d) will have a value much smaller than the DOF (280) of the imaging system to facilitate the imaging.

To improve the thermal stability of the present HEMT, a layer of passivation material such silicon nitride and silicon oxide, silicon oxide nitride, magnesium oxide, hafnium oxide, aluminum oxide and their mixtures is deposited on the top surface of the HEMT. As the technology of passivation for transistor devices is not the scope of this invention, more description will not be given.

The substrate may be silicon, silicon carbide, sapphire and GaAs as long as their crystalline quality is suitable for epitaxial growth of the III-nitride layers. Materials for the III-nitride layers may include AlN, GaN, InN, AlGaN, InGaN, AlInN and their alloys. Materials for the drain contact and the source contact can be selected from a combination of metals such as Ti, W, Pt, Al, Au, Cu as long as the first metal contacting the composite epitaxial layers can make a low contact resistance. Materials for the gate can be selected from a metal group including Ni, Ta, W, Pt, Al, Ti and Au as long as the first metal contacting the channel gate region can make a rectifying Schottky contact.

### Etching Process

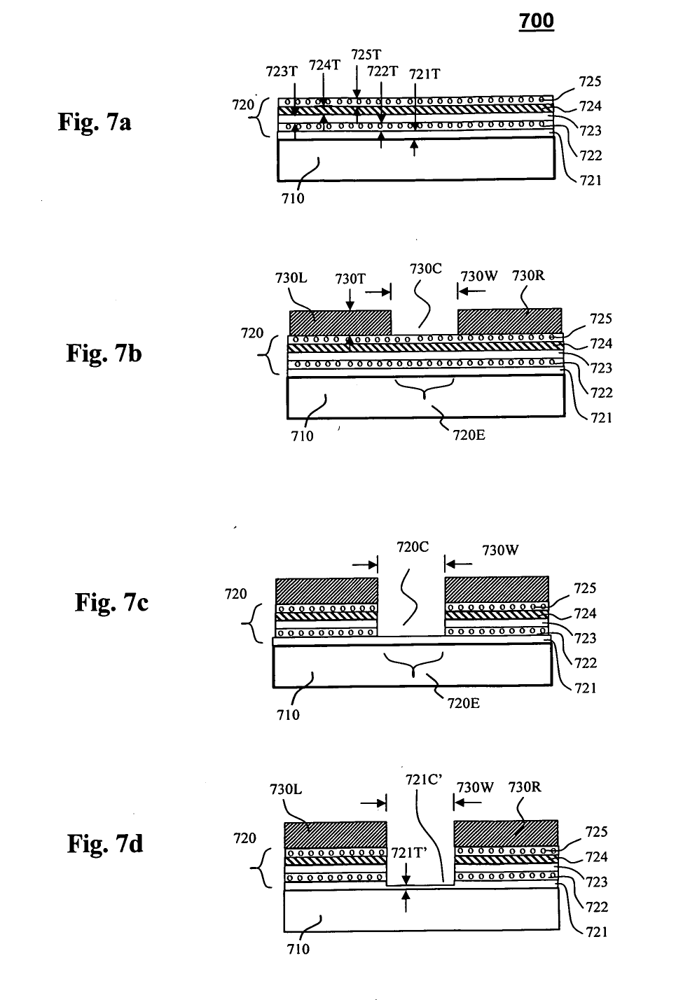

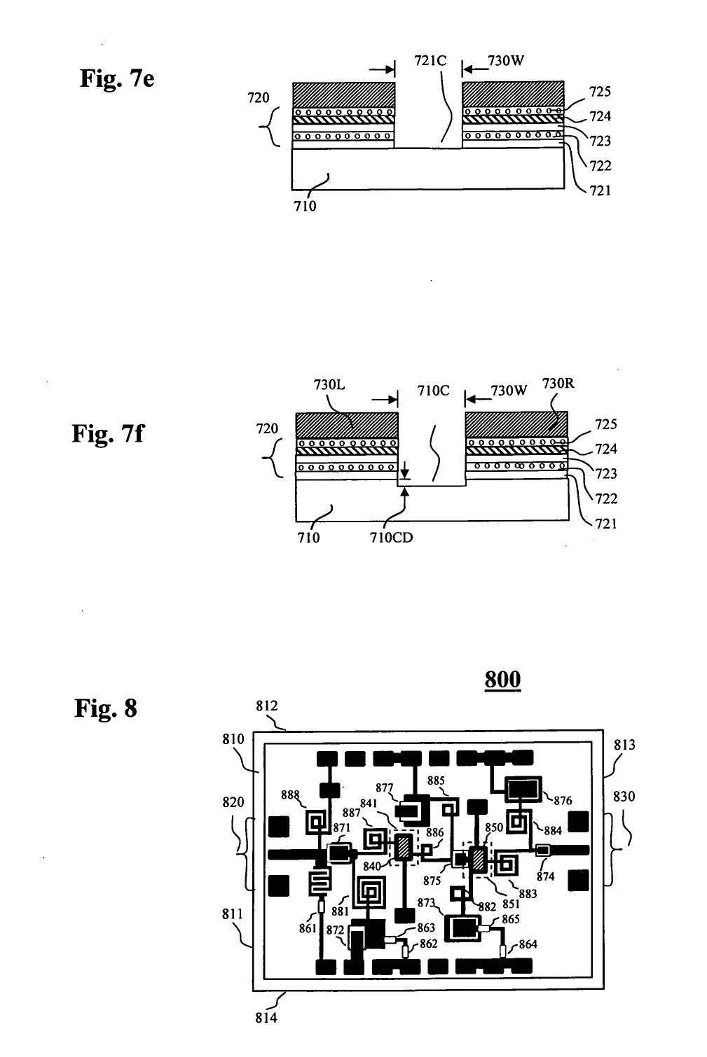

Although the second grooving process is used as an example in the following descriptions, it should be noted that this etching process can be used for both the second grooving process and for the first grooving process. Etching of materials in composite epitaxial layers may be achieved using conventional photolithography and dry etching. As shown in FIG. 7a, sample (700) comprises a substrate (710) with composite epitaxial layers (720) deposited on the top surface. The composite epitaxial layers comprise a first buffer layer (721) with a first buffer layer thickness (721T), a conductive channel layer (722) with a conductive layer thickness (722T), a Schottky barrier layer (723) with a Schottky barrier layer thickness (723T), a ledge layer (724) with a ledge layer thickness (724T), a doped ohmic contact layer (725) with a doped ohmic contact layer thickness (725T). On top of the composite epitaxial layers a first photoresist layer (730L, 730R, FIG. 7b) with a first photoresist layer thickness (730T) is applied and exposed by a dicing lane pattern through a first photomask to create a dicing lane photoresist cavity (or groove) (730C) with a dicing lane photoresist cavity width (730W) to expose a portion (720E) of said composite epitaxial layers (720). The exposed composite epitaxial layers portion (720E) is then etched by a chemical etching or more preferably by a dry etching to generate a composite epitaxial layer cavity (or groove) (720C, FIG. 7c) to expose the buffer layer (721). Said composite epitaxial layer cavity (or groove) (720C) may represent any one of the dicing lanes (680-1, 680-2, 680-3, 680-4, 6805-5, 680-6 or 685-1, 685-2, 685-3, 685-4, 685-5, 685-6, 685-7) as shown in FIG. 6c and it can also represent any one of the field lanes (550-1, 550-2, 550-3, 550-4, 550-5, 550-6, 550-7, 550-8, 560-1, 560-2, 560-3, 560-4, 560-5, 560-6, 560-7, 560-8) shown in FIG. 5b. The strain or stresses induced in the substrate (710) due to the deposition of the composite epitaxial layers (720) are thus decreased by the generation of the composite epitaxial layer cavities or grooves.

According to another embodiment of the present invention, above-described etching may be continued so that the buffer layer in the exposed region (721C′) is etched down to a thickness (721T′, FIG. 7d) so that the strain or stresses induced in the substrate may be reduced further. Alternately, the etching can be performed so that the exposed buffer layer (721) is completely removed to expose the substrate (710), as shown in FIG. 7e or the etching is continued still to so that a material from a top substrate region (FIG. 70 is removed from the substrate to form a substrate top cavity (710C) with a substrate top cavity depth (710CD). However, the amount of over etch should be controlled to a limited level. Otherwise, the strength of the wafer may be reduced even after the induced strain or stresses have been released. Such a reduction in the strength of the wafer may lead to possible breakage during processing and handling of the wafers.

According to this invention, the composite epitaxial layers are III-nitride layers selected from a material group of AlN, GaN, InN, AlGaN, InGaN, AlInN and their alloys where as substrate is selected from a material group of sapphire, SiC and Si.

When fabricating a high electron mobility transistor based MMIC on composite epitaxial layers coated substrate with substantial deformation from stain or stresses, the uniformity of the width of the smallest features can be improved further and the unwanted formation of microcracks during processing can be further reduced according to yet another embodiment of this invention. As shown in FIG. 8, a simplified schematic top view of a typical low noise amplifier MMIC microchip (800) is shown. The MMIC microchip (800) is fabricated on a substrate (810) and it has an input port (820), an output port (830), a first stage HEMT (840, LNA MMIC) inside an area (841), a second stage HEMT (850) inside an area (851), biasing components (861 - - - 888) including resistors (861, 862, 863, 864, 865), capacitors (871, 872, 873, 874, 875, 876, 877) and inductors (881, 882, 883, 884, 885, 886, 887, 888). Said first stage HEMT and second stage HEMT are active components and said resistors, capacitors and inductors for biasing are passive components. The arrangements of active components and passive components in FIG. 8 are for illustration purpose and the role for each component will be clear to those skilled in the art without further description. It is noted that areas (841, 851) for the construction of the HEMT (840, 850) are quite small as compared to the total area of the substrate (810), hence the majority of the substrate surface is occupied by the passive components: resistors, capacitors, inductors, transmission lines for interconnect, input port and output port. For practical LNA MMIC, the fraction of substrate surface being occupied by active HEMTs is less than 5% or even less than 2%. This is also the case for power amplifier MMIC. The passive components in said LNA MMIC and power amplifier MMIC do not require the functions of composite epitaxial layers. Hence, according to another embodiment of this invention, an MMIC for power amplification or conditioning of microwave signals comprises a substrate (810) having four substrate edges (811, 812, 813, 814), an input port (820), an output port (830), a first stage HEMT (840) fabricated in substantially central region of a first composite epitaxial layer HEMT region (841), a second stage HEMT (850) fabricated in substantially central region of a second composite epitaxial layer HEMT region (851), passive components (861, 862, 863, 864, 865, 871, 872, 873, 874, 875, 876, 877, 881, 882, 883, 884, 885, 886, 887 and 888) for biasing of said first stage HEMT and said second stage HEMT, transmission lines for interconnect signal from the input port (820) through said HEMTs to the output port (830) for amplifying and conditioning of microwave signals. Composite epitaxial layers on the substrate outside the first composite epitaxial layer HEMT region (841) and outside the second composite epitaxial layer HEMT region (851) are removed completely or partly by etching. Such etching is achieved by a photolithography process and a dry etching process or a wet etching process to minimize deformation of the substrate to facilitate the imaging during subsequent photolithography processes forming said MMIC. This will improve the critical dimension uniformity, reduce unwanted generation of microcracks and defects in the composite epitaxial layers, and improve fabrication yield and performance reliability of the MMIC.

For those skilled in the art, it is understandable that MMIC according to this invention may include additional HEMTs beyond the second stage HEMT. Hence, there could be a third stage HEMT or even a fourth stage HEMT to achieve desired performance of the MMICs. According to yet another embodiment of this invention, after the etching of composite epitaxial layer, the substrate area outside the first composite epitaxial layer HEMT region (841) and outside the second composite epitaxial layer HEMT region (851) is covered by a layer of insulator such as silicon nitride, silicon oxide, silicon oxide nitride, magnesium oxide, hafnium oxide, aluminum oxide and their mixtures. It is preferred for such insulator layers to have a large breakdown electric field and low stresses so as not to cause further deformation of the substrate.

### Reducing the Effects of Grooving Processing on HEMTs

After the first and the second grooving processes, stress and strain in the substrate and in the composite epitaxial layers are reduced and the uniformity of the critical dimension is improved. However, the etching of epitaxial layers in the field lanes and in the dicing lanes will also change the strain and stress between individual layers of the composite layers. As described before, appropriate stresses is necessary for the operation of the high electron mobility transistors After the etching of the composite epitaxial layers in the field lanes and in the dicing lanes, the strain and stress in the Schottky layer (442S) become smaller. This will cause reduction of induced positive charge carriers in the Schottky layer and induced negative charge carriers in the channel layer (442C), which will affect the properties of the high electron mobility transistors and the MMIC based on them.

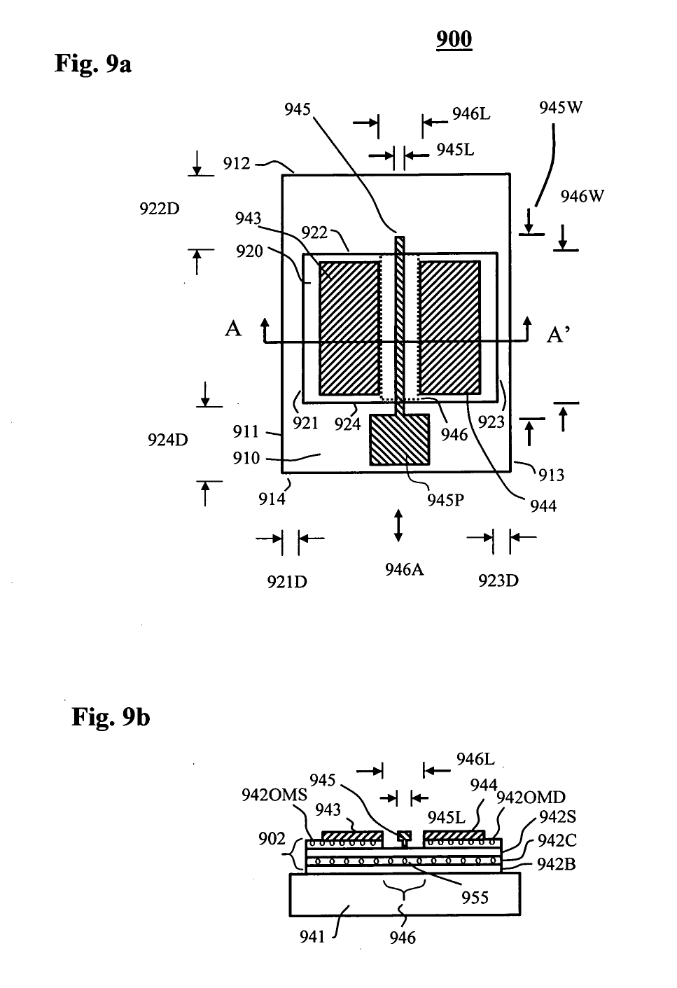

A high electron mobility transistor (900), which represents either 840 or 850 in FIG. 8, for power switching or for millimetre wave circuit applications is shown in FIG. 9a. It comprises a substrate (910), a composite epitaxial layers (920) which represents the first composite epitaxial layer HEMT region (841) and second composite epitaxial layers HEMT region (851) shown in FIG. 8. The composite epitaxial layers (920) have four composite epitaxial layers HEMT region edges: a first composite epitaxial layers HEMT region edge (921), a second composite epitaxial layers HEMT region edge (922), a third composite epitaxial layers HEMT region edge (923) and a fourth composite epitaxial layers HEMT region edge (924). A source (943) and a drain (944) defining a channel region (946) having a channel long axis (946A) a channel region width (946W), a channel region length (946L). A gate (945) having a gate length (945L), a gate width (945W) and a gate pad (945P), makes a rectifying or Schottky contact to the channel region (946). A first dicing lane edge (911), a second dicing lane edge (912), a third dicing lane edge (913) and a fourth dicing lane edge (914) form the x-axis dicing lane edges (911, 913) and the y-axis dicing lane edges (912, 914). The four composite epitaxial layers HEMT region edges form two x-axis composite epitaxial layers HEMT region edges (921, 923) and two y-axis composite epitaxial layers HEMT region edges (922, 924). The first dicing lane edge (911) and the first composite epitaxial layers HEMT region edge (921) define a first dicing lane edge to composite epitaxial layers HEMT region edge distance (921D). The second dicing lane edge (912) and adjacent second composite epitaxial layers HEMT region edge (922) define a second a dicing lane edge to composite epitaxial layers HEMT region edge distance (922D). The third dicing lane edge (913) and adjacent third composite epitaxial layers HEMT region edge (923) define a third dicing lane edge to composite epitaxial layers HEMT region edge distance (923D) and the fourth dicing lane edge (914) and adjacent fourth composite epitaxial layers HEMT region edge (924) define a fourth dicing lane edge to composite epitaxial layers HEMT region edge distance (924D).

According to yet another embodiment of this invention, values of the dicing lane edge to composite epitaxial layers HEMT region edge distance (921D, 922D, 923D, 924D) are kept to be substantially greater than 100 μm and more preferably greater than 150 μm, in order to minimize effects of changes in strain and stresses in said composite epitaxial layers HEMT region due to the removal of materials of composite epitaxial layers in the dicing lanes on the electronic performance of the high electron mobility transistor. It should be pointed out that the diagram of FIG. 9a is for illustration purposes. The dicing lane edge to composite epitaxial layers HEMT region edge distances (921D, 922D, 923D, 924D) are often comparable or greater than the channel width (946W) and channel length (946L), and thus are comparable or greater than the dimensions of the first composite epitaxial layers HEMT region (841) and second composite epitaxial layers HEMT region (851) shown in FIG. 9a.

The above-mentioned concept of keeping values of the dicing lane edge to composite epitaxial layers HEMT region edge distances (921D, 922D, 923D, 924D) to be substantially greater than 100 μm may well be adopted to the fabrication of a single high electron mobility transistor, or switching circuits and millimetre wave circuit in order to minimize effects of changes in strain and stresses in the composite epitaxial layers HEMT regions due to dicing or due to the removal of materials of composite epitaxial layers in the dicing lanes on the electronic performance of the high electron mobility transistor.

What is claimed is:

1. A microchip with improved feature uniformity and circuit performance for power switching and millimetre wave applications comprises a plurality of high electron mobility transistors each in a composite epitaxial layers HEMT region on a substrate, a plurality of resistors, capacitors, inductors, transmission lines on said substrate, said microchip having a plurality of x-axis field lanes and a plurality of y-axis field lanes defining a plurality of fields, said composite epitaxial layers comprise a buffer layer having a buffer layer thickness, a conductive channel layer, a Schottky barrier layer, a ledge layer and a doped ohmic contact layer, wherein materials of said composite epitaxial layers in said x-axis field lanes and y-axis field lanes are substantially removed to reduce deformation in said substrate to improve feature uniformity and to reduce unwanted microcracks induced in said composite epitaxial layers in channel regions of said high electron mobility transistors to increase fabrication yield and reliability of said microchips.

2. A microchip with improved feature uniformity and circuit performance for power switching and millimetre wave applications as defined in claim 1, wherein said materials of said composite epitaxial layers in said x-axis field lanes and y-axis field lanes are completely removed.

3. A microchip with improved feature uniformity and circuit performance for power switching and millimetre wave applications as defined in claim 1, wherein said materials of said composite epitaxial layers in said x-axis field lanes and y-axis field lanes are removed except for said buffer layer.

4. A microchip with improved feature uniformity and circuit performance for power switching and millimetre wave applications as defined in claim 1, wherein said materials of said composite epitaxial layers in said x-axis field lanes and y-axis field lanes are removed except for a portion of said buffer layer thickness.

5. A microchip with improved feature uniformity and circuit performance for power switching and millimetre wave applications as defined in claim 1, further comprising a partial removal of material from said substrate in said x-axis field lanes and y-axis field lanes.

6. A microchip with improved feature uniformity and circuit performance for power switching and millimetre wave as defined in claim 1, wherein said substrate is selected from a material group of silicon, silicon carbide, sapphire and GaAs.

7. A microchip with improved feature uniformity and circuit performance for power switching and millimetre wave applications as defined in claim 1, wherein materials of said composite epitaxial layers are selected from a combination of material group of AlN, GaN, InN, AlGaN, InGaN, AlInN and their alloys.

8. A microchip with improved feature uniformity and circuit performance for power switching and millimetre wave applications as defined in claim 1, wherein materials of said composite epitaxial layers are selected from a combination of material group of AlAs, GaAs, InAs, AlGaAs, InGaAs, AlInAs and their alloys.

9. A microchip with improved feature uniformity and circuit performance for power switching and millimetre wave applications as defined in claim 1, further comprising a passivation layer to enhance reliability and stability of said high electron mobility transistor, material of said passivation layer is selected from a material group of silicon nitride, silicon oxide, silicon oxide nitride, magnesium oxide, hafnium oxide, aluminum oxide and the mixtures.

10. A microchip with improved feature uniformity and circuit performance for power switching and millimetre wave applications as defined in claim 1, wherein each said composite epitaxial layers HEMT regions has four composite epitaxial layers HEMT region edges whereas each of said x-axis field lanes has a x-axis field lane edge and each said y-axis field lanes has a y-axis field lane edge, each of said composite epitaxial layers HEMT region edges and an adjacent parallel field lane edge defines a composite epitaxial layers HEMT region edge to field lane edge distance, values of said composite epitaxial layers HEMT region edge to field lane edge distances are greater than 100 micro meters and more preferably greater than 150 micro meters in order to minimize effects due to removal of composite epitaxial layers in said x-axis field lanes and y-axis field lanes on strain and stresses in said composite epitaxial layers HEMT region and to retain electronic performance of said microchip.

11. A microchip with improved feature uniformity and circuit performance for power switching and millimetre wave applications comprises a plurality of high electron mobility transistors each in a composite epitaxial layers HEMT region on a substrate, a plurality of resistors, capacitors, inductors, transmission lines on said substrate, said microchip having a plurality of x-axis dicing lanes and a plurality of y-axis dicing lanes defining a plurality of circuits, said composite epitaxial layers comprise a buffer layer having a buffer layer thickness, a conductive channel layer, a Schottky barrier layer, a ledge layer and a doped ohmic contact layer, wherein materials of said composite epitaxial layers in said x-axis dicing lanes and y-axis dicing lanes are substantially removed to reduce deformation in said substrate to improve feature uniformity and to reduce unwanted microcracks induced in said composite epitaxial layers in channel regions of said high electron mobility transistors to increase fabrication yield and reliability of said microchips.

12. A microchip with improved feature uniformity and circuit performance for power switching and millimetre wave applications as defined in claim 11, wherein said materials of said composite epitaxial layers in said x-axis dicing lanes and y-axis dicing lanes are completely removed.

13. A microchip with improved feature uniformity and circuit performance for power switching and millimetre wave applications as defined in claim 11, wherein said materials of said composite epitaxial layers in said x-axis dicing lanes and y-axis dicing lanes are removed except for said buffer layer.

14. A microchip with improved feature uniformity and circuit performance for power switching and millimetre wave applications as defined in claim 11, wherein said materials of said composite epitaxial layers in said x-axis dicing lanes and y-axis dicing lanes are removed except for a portion of said buffer layer thickness.

15. A microchip with improved feature uniformity and circuit performance for power switching and millimetre wave applications as defined in claim 11, further comprising a partial removal of material from said substrate in said x-axis dicing lanes and y-axis dicing lanes.

16. A microchip with improved feature uniformity and circuit performance for power switching and millimetre wave applications as defined in claim 11, wherein said substrate is selected from a material group of silicon, silicon carbide, sapphire and GaAs.

17. A microchip with improved feature uniformity and circuit performance for power switching and millimetre wave applications as defined in claim 11, wherein materials of said composite epitaxial layers are is selected from a combination of material group of AlN, GaN, InN, AlGaN, InGaN, AlInN and their alloys.

18. A microchip with improved feature uniformity and circuit performance for power switching and millimetre wave applications as defined in claim 11, wherein materials of said composite epitaxial layers are selected from a combination of material group of AlAs, GaAs, InAs, AlGaAs, InGaAs, AlInAs and their alloys.

19. A microchip with improved feature uniformity and circuit performance for power switching and millimetre wave applications e as defined in claim 11, further comprising a passivation layer to enhance reliability and stability of said high electron mobility transistor, material of said passivation layer is selected from a material group of silicon nitride, silicon oxide, silicon oxide nitride, magnesium oxide, hafnium oxide, aluminum oxide and the mixtures.

20. A microchip with improved feature uniformity and circuit performance for power switching and millimetre wave applications as defined in claim 11, wherein each said composite epitaxial layers HEMT regions has four composite epitaxial layers HEMT region edges, whereas each of said x-axis dicing lanes has a x-axis dicing lane edge and each said y-axis dicing lanes has a y-axis dicing lane edge, each said composite epitaxial layers HEMT region edge and an adjacent parallel dicing lane edge defines a composite epitaxial layers HEMT region edge to dicing lane edge distance, values of said composite epitaxial layers HEMT region edge to dicing lane edge distances are greater than 100 micro meters and more preferably greater than 150 micro meters, in order to minimize effects due to removal of composite epitaxial layers in said x-axis dicing lanes and y-axis dicing lanes on the strain and stresses in said composite epitaxial layers HEMT region and to retain electronic performance of said microchip.
